(19) United States
(12) Patent Application Publication
(10) Pub. No.: US 2007/0209933 A1
(43) Pub. Date: Sep. 13, 2007

(54) Sample holding electrode and a plasma processing apparatus using the same

(76) Inventors: Ken Yoshioka, Hikari (JP); Yutaka Omoto, Hikari (JP); Tsunehiko Tsubone, Hikari (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/513,070

(22) Filed: Aug. 31, 2006

(30) Foreign Application Priority Data
Mar. 9, 2006 (JP) 2006-063783

(51) Int. Cl. C23C 14/00

(52) U.S. Cl. 204/298.31

(57) ABSTRACT

A temperature control type sample-holding electrode using a heater capable of enhancing the performance of controlling the electrode temperature and ensuring the uniformity of static adsorption force over the entire surface, the sample-holding electrode being provided in a processing chamber with a sample being disposed thereon, including a dielectric film having a sample-placing surface and a thin electrode film disposed so as to oppose to the sample-placing surface by way of the dielectric film and comprising a layer of a substantially identical height serving both as a static adsorption electrode and a heater electrode, and provided with power source device capable of simultaneously supplying an AC power for heater and DC power for static adsorption to the thin electrode film.

### CLAIM OF PRIORITY

The present application claims priority from Japanese application serial JP 2006-063783 filed on Mar. 9, 2006, the content of which is hereby incorporated by reference into this application.

### BACKGROUND OF THE INVENTION

The present invention concerns a sample-holding electrode and a plasma processing apparatus using the same and, more in particular, it relates to a sample-holding electrode having a temperature control electrode and a plasma processing apparatus using the same.

In a plasma processing apparatus such as an etching apparatus, plasmas are formed in a vacuum vessel by using microwaves or high frequency waves, and an electrode for holding a sample to be processed is disposed to which a bias high frequency wave is applied, to conduct processing. The electrode chucks the sample electrostatically. At the same time, for controlling the etching uniformity and the etching shape of the sample, the temperature at the surface of the electrode is distributed in the radial direction to provide a temperature distribution at the surface of the sample.

For providing the temperature distribution on the surface of the sample, there have been known a method of arranging a plurality of supply systems of coolants such as cooling water of different temperatures in the inside of an electrode main body (first method), a method of using a plurality of supply systems for an He gas to be supplied for heat conduction between the electrode surface and the sample rear face, and controlling the pressure of He of the plurality of supply systems (second method) and, further, a method of disposing a thin heater electrode by way of a thin dielectric layer to the electrode main body (third method) have been known.

For the third method, Japanese Patent Laid-Open Nos. 2000-114354 and 2003-258056, for example, disclose an electrode structure comprising two layers, an upper layer and a lower layer in which a heater electrode is disposed below a static adsorption electrode, and Japanese Patent Laid-Open No. 2002-231793 discloses a wafer support member capable of adopting an identical electrode as a static chuck or a heater depending on the application use.

The first method involves a problem that the temperature distribution of the electrode can not be changed rapidly since this generally uses a liquid coolant. The second method includes a problem that no sufficient temperature change can be obtained within the electrode surface in a case where input heat from plasmas is small, for example, as in the etching apparatus for fabrication of LSI gates. Further, while the third method, that is, the temperature control utilizing the heater electrode can avoid the problems described above because of the good responsivity, this involves technical difficulties as will be described later.

At first, as a premise, for electrostatically chucking a sample, it is necessary to dispose a thin adsorption electrode formed, for example, of a thin W film approximately over the entire surface of the electrode below a thin dielectric film having about 100 μm thickness. The thin adsorption electrode is disposed over the entire electrode, because it is necessary to ensure the static adsorption force over the entire surface. Also in a case of adopting the method of arranging the heater electrode for the control of temperature on the sample surface, a heater electrode formed, for example, of a thin W film is disposed by way of a thin dielectric film to the electrode main body. In this case, the electrode for static adsorption described above should also be disposed.

In the prior art, the heater electrode and the adsorption electrode had to be disposed as two layers of an upper layer and a lower layer. Use of such a two-layered structure involves a problem that the adsorption becomes insufficient in a case where the adsorption electrode is situated below and the temperature control becomes insufficient in a case where the heater electrode is situated below as disclosed in the Japanese Patent Laid-Open Nos. 2000-114354 and 2003-258065. Further, the technique of burying the two layers of thin films in the thin film dielectric layer is difficult to result in a problem of increasing the cost as well. The system described in JP-A No. 2002-231793 discloses nothing for simultaneous provision of the heater electrode and the adsorption electrode.

### SUMMARY OF THE INVENTION

The present invention intends to provide a sample-holding electrode capable of attaining enhancement in the performance of the electrode temperature control and ensuring uniformity for the entire surface of the static adsorption force in one electrode layer.

In order to solve the foregoing subject, in a sample-holding electrode, an electrode film of serving both as the heater electrode and the adsorption electrode is attained substantially by one layer according to the invention.

The present invention provides, in one aspect, a sample-holding electrode provided in a processing chamber to which a sample (a substrate) is disposed including, a dielectric film having a sample-holding surface, a thin electrode film disposed so as to oppose the sample-holding surface by way of the dielectric film, a layer having a substantially same height overall serving both as a static adsorption electrode and a heater electrode, and a power source device capable of simultaneously supplying an AC power for heater and DC power for static adsorption to the thin electrode film.

According to the present invention, the average temperature and the radial temperature distribution for the sample surface on the electrode can be changed at a high speed while reliably adsorbing the entire surface of the sample by static adsorption force with a simple constitution. This can ensure the etching rate and the shape uniformity within the sample plane.

### BRIEF DESCRIPTION OF THE DRAWINGS

FIG. 1 is a cross sectional view for a detailed structure of an electrode of a first embodiment according to the present invention;

FIG. 2 is a cross sectional view showing a first embodiment of a sample-holding electrode using the invention;

FIG. 3 is a view showing a planar structure of the electrode of the first embodiment according to the invention;

FIG. 4 is a view for explaining the operation of static adsorption by a static adsorption area including a non-heater/exclusive adsorption area;

FIG. 5 is a graph showing control examples of temperature distribution on an electrode in a case of using the first embodiment of the invention;

FIG. 6 is a view showing an example of an electrode structure according to a second embodiment of the invention;

FIG. 7 is a view for explaining a detailed structure inside a base electrode according to the second embodiment; and

FIG. 8 is a view showing the operation of electrostatic adsorption in a monopole type electrode.

### DESCRIPTION OF PREFERRED EMBODIMENTS OF THE INVENTION

The present invention is to be described by way of embodiments with reference to the drawings.

### Embodiment 1

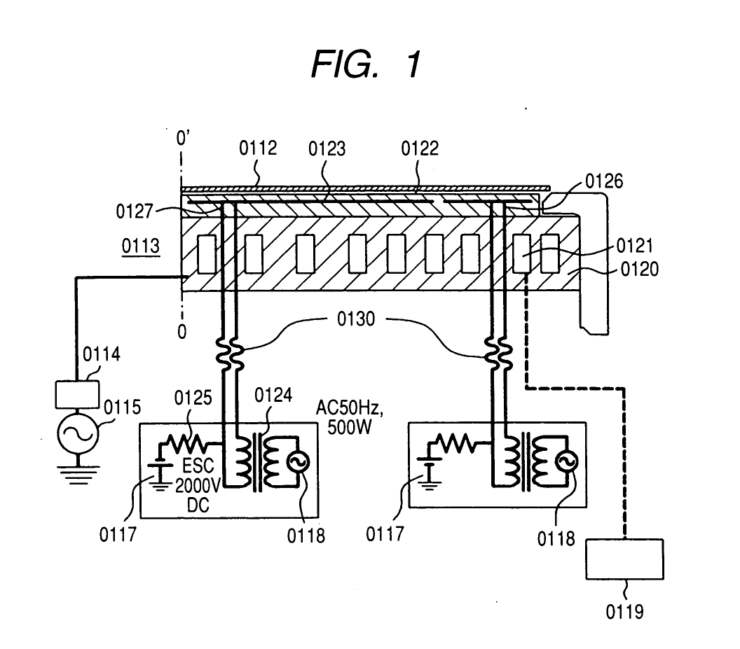

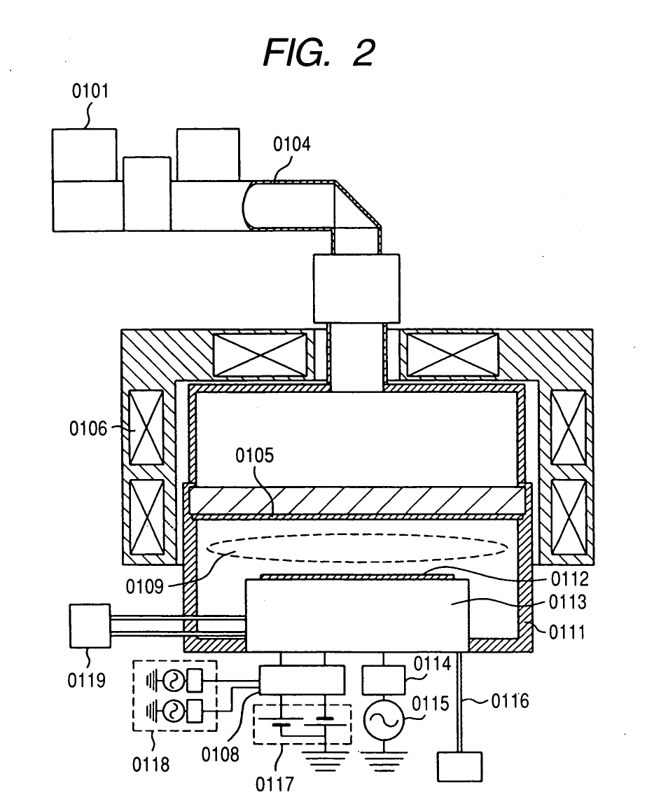

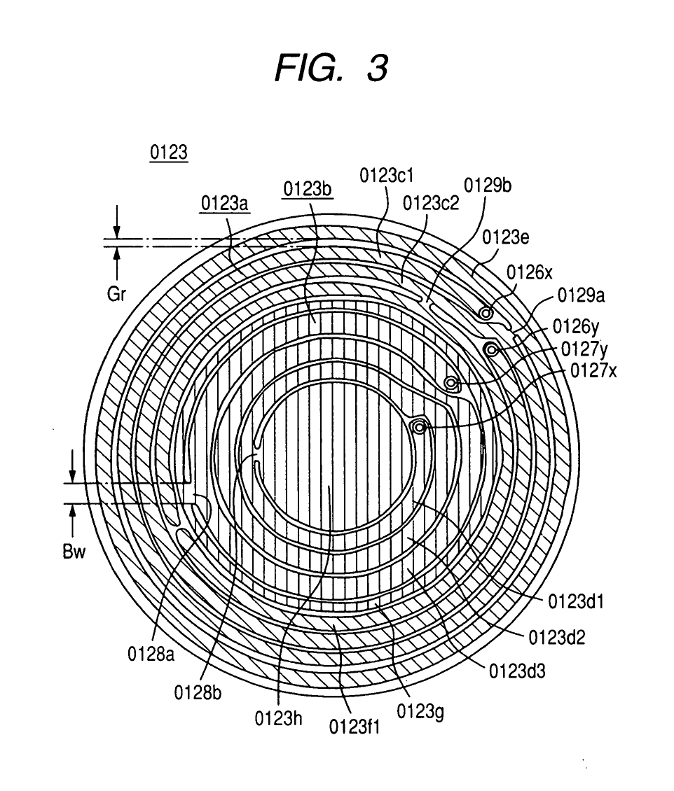

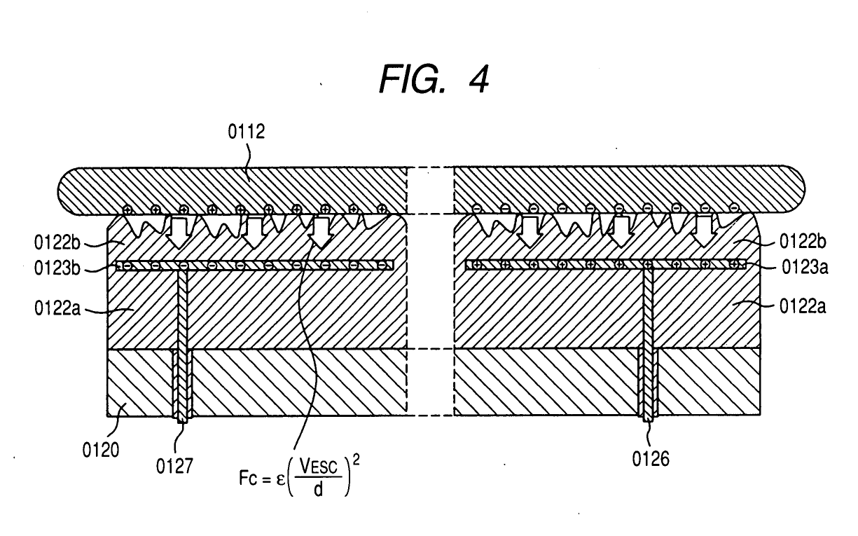

Embodiment 1 of the present invention is to be described with reference to FIG. 1 to FIG. 5. FIG. 1 is a view showing a detailed structure of a sample-holding electrode according to Embodiment 1 of the invention. FIG. 2 is a longitudinal cross sectional view showing the outline for the constitution of an etching apparatus adopting the sample-holding electrode according to Embodiment 1. FIG. 3 shows a planar structure of a dual-purpose electrode for heater and adsorption. FIG. 4 is a view showing a longitudinal cross sectional structure of the dual-purpose electrode for heater and adsorption, and describes the function as well.

At first, a detailed structure inside the sample-holding electrode is to be described with reference to FIG. 1. A base electrode (electrode main body) 0113 has a base member 0120 and a thin dielectric film 0122. That is, the base member 0120 formed of a metal such as Al or Ti is present in a lower portion of the electrode main body, in which a channel 0121 for making a temperature controlling coolant flow for controlling the temperature of the base member is formed. The channel 0121 is connected at the outside with a temperature controller 0119 and, for example, the circulation amount of a liquid coolant is controlled. A bias power source 0115 is connected to the base member 0120.

A thin dielectric film 0122 such as of Al₂O₃ is formed, for example, by a flame spraying method on the base member 0120. The thin dielectric film 0122 has in the film a thin electrode film (dual-purpose electrode for heater and adsorption) 123 functionally both as a heater electrode and a static adsorption electrode, and a static adsorption power source (DC power source) 0117 and a heater power source (AC power source) 0118 are connected to the thin electrode film 0123.

The method of forming the thin dielectric film 0122 includes the steps of: forming a first thin dielectric film comprising 100 to 300 μm of Al₂O₃ (0122a in FIG. 4) over the base member 0120 by a flame spraying method; flame spraying thereover a metal material such as of tungsten W to a thickness of 10 to 100 μm to form the thin electrode film 0123 comprising a layer of a substantially identical height (thickness); and then again flame spraying thereover a second thin dielectric film comprising Al₂O₃ (0122b in FIG. 4) to a thickness of 50 to 150 μm.

As a metal material to be flame sprayed for forming the thin electrode film, while W has been shown as an example in the foregoing description, it may be a nickel-chromium alloy controlled for the resistivity so as to be suitable as a heater, or may be a material controlled for the resistivity by mixing an appropriate addition metal to W. Also the thickness of the flame sprayed metal is determined depending on the resistivity of a metal material used, a heat generation power required, voltage and current performance that can be supplied from the power source and a wire width of the heater electrode to be used.

On the surface of the second thin dielectric film, there are formed a sample-placing surface for placing a sample (a work substrate to be processed) 0112 and a concave portion as a gap into which an He gas flows.

The base electrode 0113 has a He supply system 0116 for conducting heat conduction to the work substrate 0112 and the sample-placing surface of the electrode (refer to FIG. 2), and a He gas is supplied by way of a channel to the concave portion or the like.

The base electrode 0113 is connected byway of an automatic matching device 0114 to a bias power source 0115. Further, the base electrode 0113 is connected to a DC power source 0117 for static adsorption and a heater power source 0118 for temperature control of heater. That is, a power source device for the dual-purpose electrode for heater and adsorption for supplying AC current superposed on DC current is connected with the dual-purpose electrode 123 for heater and adsorption.

A power feed source having integrated heater power source and static adsorption power source is connected to the outside of the electrode main body. As described above, one of the features of this embodiment is to adopt a circuit integrating the heater feed circuit and the static chuck feed circuit.

As the heater power source 0118, a commercial power source (50/60 Hz) of 500 W is used and, as the static adsorption power source 0117, a DC power source capable of outputting 100 to 2000 V is used for instance. The heater power source 0118 is coupled by way of an insulating transformer 0124 with the static adsorption power source 0117. Since the static adsorption power source 0117 having a rated current value of from 0.1 to 10 mA and a rated voltage of from 100 to 2000 V is used, a current limiting resistor 0125 is attached for protection of the circuit. For the heater power source 0118, a variable voltage power source, for example, at a voltage of 10 to 200 V is used and a current of about 1 to 20 A is used. With such a circuit constitution, the heater power source 0118 and the static adsorption power source 0117 can apply the AC current and the DC current to one identical dual-purpose electrode 0123 without interfering each other.

In the foregoing description, while the insulating transformer 0124 is used such that the DC high voltage does not enter the heater power source 0118, an insulating capacitor may also be adopted instead of the insulating transformer.

A cut filter 0130 is disposed on the feed line to the thin electrode film 0123 for heater and static adsorption such that a high frequency bias current does not enter. That is, while the high frequency current is outputted from the bias power source 0115 and is then supplied by way of the base member 0120 to the sample 0112. On the other hand, it tends to leak by way of the layer of the thin electrode film 0123 of the heater power source/static adsorption power source (0117, 0118). For preventing the leakage, the cut filter 0130 is disposed in the midway. An inductance is used usually as the cut filter.

Then, an etching device adopting the sample-holding electrode is to be described with reference to FIG. 2. The etching apparatus has a processing chamber 0111, and on the inside of the processing chamber 0111, a base electrode 0113 having a work substrate 0112 as an object for processing placed thereon is disposed. An evacuation system and a gas introduction system (not shown) are connected to the processing chamber 0111, capable of maintaining an atmosphere and a pressure suitable to plasma processing. In the upper portion of the processing chamber 0111, a plate shaped quartz window and a dispersion plate 0105 are disposed above the work substrate 0112. By a gas introduction system, a processing gas is dispersed and supplied to the space above the base electrode 0113 in the processing chamber 0111 from a plurality of openings formed in the dispersion plate 0105. A microwave source 0101 as electromagnetic radiation means feeds microwaves or electromagnetic waves in a UHF band. The microwaves, etc. are transmitted along the wave guide 0104 and radiated into the processing chamber 0111. On the other hand, a plurality of coils 0106 as magnetic field feed means are disposed at the periphery of the upper portion of the processing chamber 0111. The wall of the processing chamber 0111 is grounded to the earth.

The work sample 0112 is adsorbed and held on the base electrode 0113, and the processing gas fed in the processing chamber 0111 is converted into plasmas (0109) by the microwaves charged from the electromagnetic wave radiation means, and can conduct predetermined plasma processing to the work sample 0112. The temperature distribution at the surface of the work sample 0112 is controlled by the base electrode 0113.

A bias potential at about 400 KHz to 4 MHz can be applied to the work sample 0112 on the base electrode 0113 from the bias power source 0115 by way of the automatic matching device 0114. This can draw ions in the plasmas 0109 to the work substrate to increase the speed and enhance the quality of the plasma etching processing.

Reaction products formed upon processing of the work substrate 0112 are exhausted from an exhaust port located below the base electrode 0113 by the operation of a vacuum pump (not illustrated) connected therewith.

The plasma generation means is not restricted to the means described above of using the microwaves but plasma generation means by electrostatic coupling means or induction coupling means using high frequency waves may also be used.

In this embodiment, since the work substrate 0112 is adsorbed to the sample-placing surface by a coulomb force applied between the application DC voltage on the W electrode and the sample, the thickness for the upper portion 0122b of the thin dielectric film 0122 made of Al₂O₃ is reduced to such an extent as causing no problem in view of withstanding voltage. For example, in order to obtain an adsorption force of about 10 kPa while setting the application voltage to 1500 VDC, the thickness for the upper portion 0122b of the thin dielectric film 0122 is set to 100 μm.

In this embodiment, while the thin dielectric film 0122 has been described as an example of the flame-sprayed film, it may be generally also an insulator membrane such as a sintered film or a crystal film.

In this embodiment, the thin electrode film (dual-purpose electrode for heater and adsorption) 0123 is adapted as a dipole type static adsorption system and the thin electrode film 123 is formed being generally divided into an inner circumferential side and an outer circumferential side. The outer adsorption electrode and the inner adsorption electrode are defined such that each of them has a substantially identical area, and positive and negative electrodes, for example, of +1500 V and −1500 V are applied. The dipole system is adopted because adsorption can be started previously by applying the adsorption voltage before firing of the plasmas after transporting the sample to the electrode and holding the sample thereon.

Further, the adsorption system for adsorbing the sample may also be a system of utilizing Johnson-Rahbek force in addition to the coulomb adsorption system described above. In this case, the dielectric film can be obtained by spraying, for example, those containing additives such as titanium oxide to Al₂O₃.

FIG. 3 shows an example of a planar structure of the thin electrode film 0123 adopting the dipole system of this embodiment. The thin electrode film 0123 has an outer adsorption electrode 0123a and an inner adsorption electrode 0123b corresponding to the entire surface of a substantially circular sample-placing surface, in which a certain area in each of them is defined as a common area 0123c (c1, c2) serving both as the outer heater electrode and the adsorption electrode, and a common area 0123d (d1, d2, d3) serving both as the inner heater electrode and the adsorption electrode. Each of the outer and the inner common areas has a circular or spiral electrode surface of substantially constant width and constant height having a radial gap Gr and is supplied with an AC power at a commercial frequency for use in heater from two outgoing and incoming terminals 126x, 126y: and 127x, 127y. In other words, an outside heater electrode is formed when AC power is applied from the two terminals 126x, 126y to both ends of the common area 0123c, while an inside heater electrode is formed when an AC power is applied from the two terminals 127x, 127y to both ends of the common area 0123d.

In the example of FIG. 3, 3-turns for the inside and 2-turns for the outside are illustrated as the common area. The number of turns is generally a single turn or plural turns.

The radial gap Gr of the circular or spiral electrode surface is from 0.5 mm to 1.0 mm.

On the other hand, the static adsorption area comprises the two inner and outer common areas (0123c, 0123d) and one or plurality of branch areas. That is, the static adsorption area comprises the common areas and, in addition, the branch areas, that is, non-heater exclusive adsorption areas (0123e, 0123f, 0123g, 0123h) connected with the common areas by way of narrow bridge portions (0128a, 0128b, 0129a, 0129b).

For example, the branch areas 0123e and 0123f1 of the outside adsorption electrode are present on the outside and the inside of the terminal 126x and terminal 126y, and narrow bridge portions 0129a, 0129b are present between the common areas 0123c1 and 0123c2. Accordingly, the branch areas do not substantially constitute an electrical circuit when AC power is applied between the two terminals 126x, 126y. In the same manner, the branch areas 0123h, 0123g of the inside adsorption electrode are present at the outside of the terminal 127x and the terminal 127y, and the narrow bridge portions 0128a and 0128b are present between the common areas 0123d1 and 0123d3. Accordingly, also the branch areas do not constitute the heater electrode area.

That is, for the entire adsorption area, a DC voltage is supplied uniformly in the common mode from the terminals 126x, 126y, 127x, and 127y to generate the adsorption force over the entire adsorption area. Further, current for heater does not flow into the exclusive adsorption area.

It may suffice to dispose the electrode surface in the branch area by effectively utilizing the space of the sample-placing surface and it is not always necessary that the planar shape is restricted to a certain shape. As described above, the planar structure of the electrode is devised for attaining the dual-purpose electrode for heater and adsorption.

The bridge portion (0128a, 0128b, 0129a, 0129b) for connecting the branch area and the common area is disposed only at one circumferential position so that the heater current does not enter. In a case of forming plural bridge portions between both of the areas, since input/output ports are formed to the branch area, the heater current should flow. The width Bw of the bridge portion is preferably about from 1 to 10% of the circumferential length near the bridge portion.

It is desirable that the height for the common area and that for the branch area are substantially identical and preferably formed as low as possible. The height may of course be different somewhat between the common area and the branch area, but it is preferred to form them as layers of a substantially identical height.

The common area and the branch area are formed simultaneously by using an identical material in one process as the dual-purpose electrode. However, the branch area not forming the dual-purpose electrode for heater and adsorption may also be manufactured with material and process different from those of the area for the dual-purpose electrode.

Then, the operation of static adsorption by the entire static adsorption area that includes the heater area and the non-heater exclusive adsorption area is to be described with reference to FIG. 4. When a high DC voltage for static adsorption is applied from the terminals 126x, 126y; 127x and 127y to the thin electrode film 0123, positive and negative charges are induced between the work substrate 0112 and the thin electrode film 0123 and a force Fc exerts on the sample by the static electricity between the charges. In this case, between the terminals 126 and 127, the resistance value of the thin electrode film 0123 is, for example, 30Ω while the resistance value of the thin dielectric film 0122b is, for example, 2 MΩ since the resistivity is from 10⁸ to 10¹⁶ Ωcm. The resistance value of the work substrate 0112 is about from 2 to 5 Ω since the resistivity is about 10 Ωcm. That is, the resistance value of the thin dielectric film 0122b is much higher compared with the resistance value of the thin electrode film 0123 and that of the work substrate 0112. Accordingly, the current does not localize to a certain region but flows substantially through the entire surface of the thin dielectric film 0122 that corresponds to the entire static adsorption area.

Further, while AC power for the heater is also supplied simultaneously to the thin electrode film 0123 between the terminals 126x and 126y and between the terminals 127x and 127y for the control of heater temperature, since the resistance value of the thin electrode film 0123 is much lower compared with the resistance value of the thin dielectric film 0122, it will be apparent that the heater current flows only through the heater area.

Accordingly, when a high DC voltage is applied between the terminals 126 and 127, since the current flows through the entire thin dielectric film 0122b irrespective of the electrode pattern and irrespective of the AC power supplied to the heater area, positive and negative charges are induced uniformly between the sample and the thin electrode film 0123 corresponding to the entire surface of the sample 0131 to generate uniform static electricity.

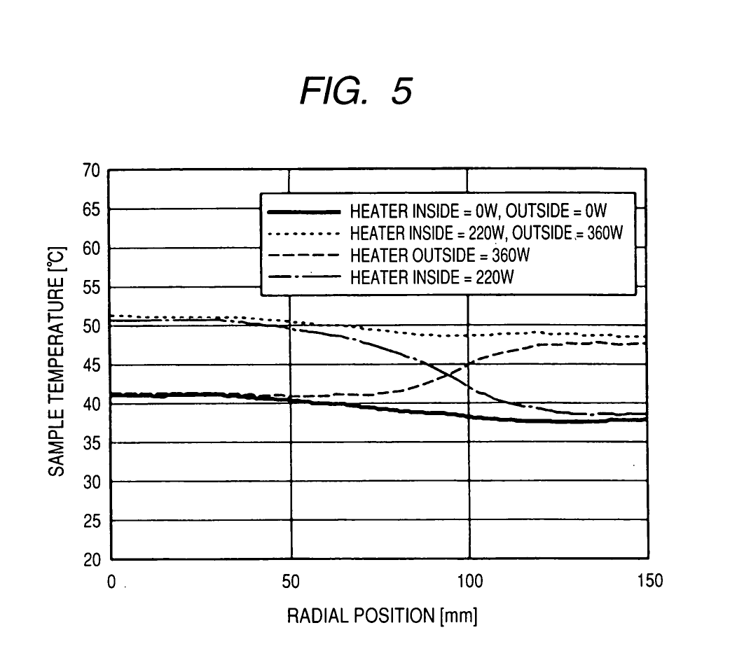

The area and the position defined for the heater area are decided in accordance with the required specification of the temperature control range for the surface temperature of the sample. For example, design examples thereof are shown in FIG. 5. The calculation conditions are as shown below.

He gas pressure=1 KPa, radial position of inside heater area=0 to 95 mm, radial position of outside heater area=100 to 145 mm, plasma input heat=160 W (parabola distribution), and material for flame-sprayed film=Al₂O₃, material for substrate=Al.

According to FIG. 5, a convex temperature distribution with a smooth temperature difference can be formed for the surface temperature of the sample by defining the inside heater to 220 W and the outside heater to 0 V. On the other hand, a concave temperature distribution can be formed by defining the inside heater too Wand the outside heater to 360 W. Further, a substantially flat temperature distribution can be obtained by charging heater power on both sides (inside 220 W, outside 360 W) in which temperature can be elevated by about 10° C. entirely compared with a case of charging 0 W to both sides.

In the etching apparatus, a work sample is often formed of a multi-layered film and the surface temperature distribution and the average temperature suitable to respective films are often different. Accordingly, it is necessary for the electrode to switch the electrode temperature at a high speed within several seconds on every change of the film in the multi-layered film to be etched. The temperature variable electrode of the dual-purpose heater adsorption electrode system according to this embodiment substantially comprises a single layer and, since the distance between the heater electrode and the sample-placing surface can be shortened different from the electrode of the two upper and lower layered structure, the responsivity is good. Accordingly, this can sufficiently cope with the high speed change for temperature switching. Further, since a wide heater area can be ensured while ensuring the static adsorption force, various temperature characteristics can also be controlled. This enables to improve the performance for the control of the electrode temperature, attainment of the entire uniformity of the adsorption force, and reduction of the cost, which were impossible so far.

While this embodiment is described for the case of the two system heater, the heater may generally be formed as plural systems. In the two system heater of this embodiment, while convex, flat, and concave distributions can be formed for the sample surface temperature, the degree of convexity of the convex distribution may sometimes be different subtly even for an identical convex distribution, depending on the film to be etched. That is, it is necessary to control the temperature at an intermediate portion between the inner circumference and the outer circumference of the sample such that it is higher by several ° C. or lower by several ° C. Accordingly, a constitution of having third and fourth heater electrodes at the intermediate portion is useful.

As described above according to this embodiment, the heater electrode area and the static suction area of different sizes can be used simultaneously and according to the application use due to the simple structure of having a dual-purpose electrode for heater and adsorption formed to a common layer and a power source for static adsorption and a power source for heater connected therewith. Accordingly, the average temperature and the radial temperature distribution at the surface of the sample on the electrode can be changed at a high speed while reliably adsorbing the approximately entire surface of the sample by the static adsorption force. This can ensure etching rate and the uniformity of the shape within the plane of the sample.

### Embodiment 2

The present invention is effective also to a monopole type static adsorption electrode.

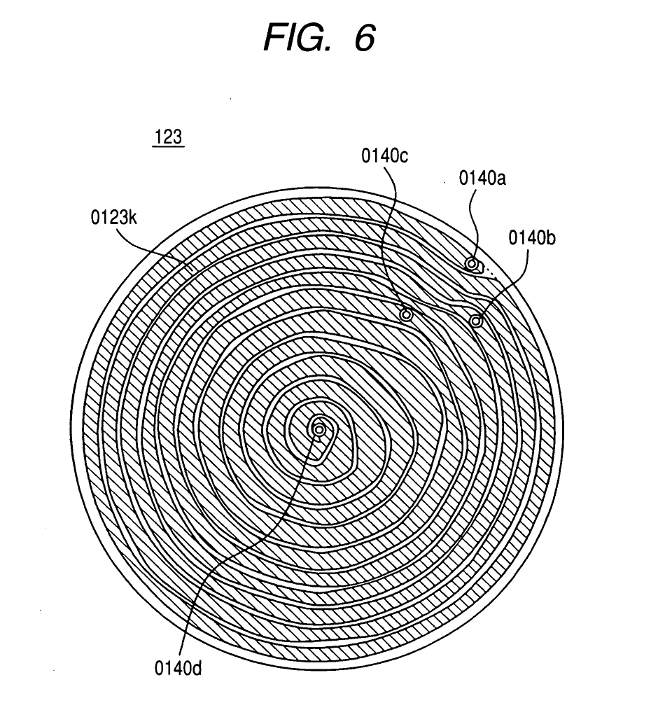

FIG. 6 shows an example of an electrode structure according to a second embodiment of the invention. As a thin electrode film, a continuous band-like electrode surface 0123k is formed spirally at 0.5 mm to 1.0 mm of a radial gap to constitute a dual-purpose thin electrode film 0123 for heater and adsorption. In this embodiment, heater terminals connected with the thin electrode film are present by the number of four as 0140a, 0140b, 0140c, and 0140d near the outer circumference, a central portion and intermediate portions between them on the sample-placing surface. The heater area in the thin electrode film is divided into three regions of 0140a to 0140b, 0140b to 0140c, and 0140c to 0140d between each of the terminals.

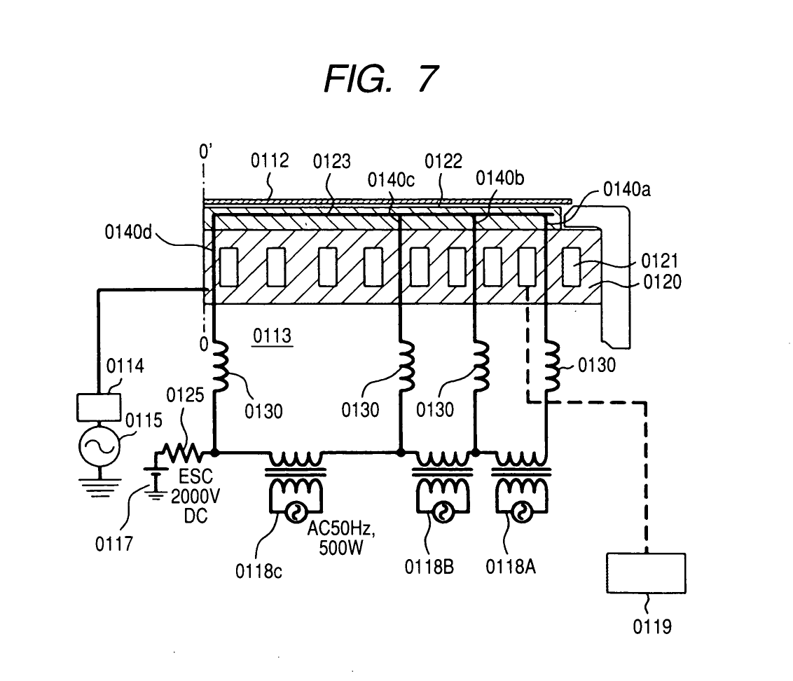

With reference to FIG. 7, the detailed structure inside abase electrode 0113 of the second embodiment is to be described. A thin dielectric film 0122 is formed by the same method as described for Embodiment 1. For example, a first thin dielectric film comprising Al₂O₃ of 100 to 300 μm thickness is formed by a flame spray method over a base member 0120, a metal material such as W is flame sprayed thereon to a thickness of 10 to 100 μm in accordance with a pattern shown in FIG. 6 to form a thin electrode film 0123 comprising a layer of a substantially identical height (thickness) thereon and, further, a second thin dielectric film comprising Al₂O₃ is flame sprayed at a thickness of 50 to 150 μm thereon.

In this embodiment, the electrode for static adsorption is a monopole type in which a DC power source 0117 of a positive or negative polarity capable of outputting 0.1 to 10 μA of current and 100 to 2000 V of voltage is connected by way of a current limiting resistor to each of the heater terminals 0140a, 0140b, 0140c, and 0140d. Further, corresponding to the three regions of the heater, each of a first AC power source 0118A, a second AC power source 0118B, and a third AC power source 0118C for heater each having an insulating transformer is connected between each of the terminals 0140a, 0140b, 0140c, and 0140d. Each of the heater sources is constituted such that the output can be controlled at a commercial frequency (50/60 Hz) and within a range of 10 to 200 V and 500 W or less, respectively. A cut filter 0130 is disposed on the feed line to each of heater terminals 0140a, 0140b, 0140c, and 0140d for the dual-purpose electrode 0123 for heater and adsorption such that a high frequency bias current does not enter.

Since the first to third AC power sources are disposed corresponding to the three-regions of the heater, the temperature for each of the heater regions can be controlled individually by the three-region heaters by which the radial temperature distribution of the sample can be controlled optionally. For example, in a case where the temperature distribution is a convex distribution and the degree of convexity is different subtly depending on the film to be etched, the temperature for the intermediate portion between the inner circumference and the outer circumference of the sample can be controlled so as to be higher by several ° C. or lower by several ° C.

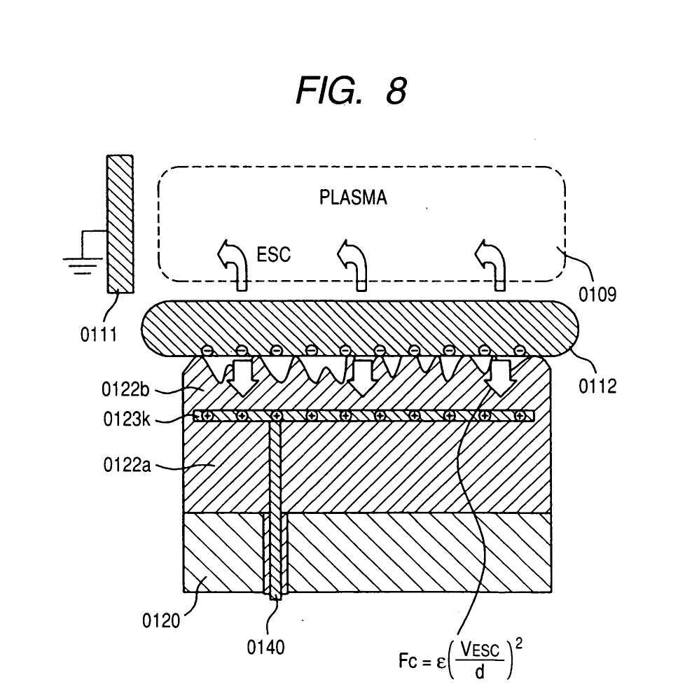

With reference to FIG. 8, the operation of static adsorption in the monopole type electrode is to be described. When a high DC voltage is applied to the thin electrode film (W electrode) 0123 in a state of firing the plasma, an electric circuit is established from the thin electrode film by way of the sample and the plasma to the ground potential on the wall of the processing chamber 0111, and a current at about 100 μa to 1,000 μA flows as an ESC current. Also in this case, the resistance value of the thin dielectric film 0122b is much higher than the resistance values for the thin electrode film, the sample, the plasma, and the processing chamber wall. Accordingly, current flows through the entire surface of the thin dielectric film with no localization to a specified region. Accordingly, negative and positive charges are induced uniformly between the entire surface of the work substrate 0112 and the thin electrode film 0123 to generate uniform static electricity.

The heater may be of any plural system. Further, while the heater is of the three-system in this embodiment, it may be substantially formed as a two-heater system, for example, by reducing the output from the second AC power source 118B to zero depending on the application use. Further, the electrode area is not restricted to one spiral band area shown in the embodiment. Any dual-purpose electrode for adsorption may be used so long as it can provide adsorption function capable of substantially covering approximately entire sample-placing surface substantially. For example, it may be constituted such that one band-like electrode area comprising a plurality of linear areas extending in parallel and an arcuate area connecting each of the terminal ends of the linear areas substantially covers the approximately entire plane of the sample-placing surface.

According to this embodiment, with a simple constitution having a dual-purpose electrode for heater and absorption formed in a common layer, and an electrostatic adsorption power source and a heater power source connected therewith, a plurality of heater electrode areas capable of generating different outputs and a static adsorption area adsorbing the entire surface of the sample can be used simultaneously and depending on the application use. Accordingly, the average temperature and the radial temperature distribution at the surface of the sample on the electrode can be changed at a high speed while reliably adsorbing the approximately entire surface of the sample by the static adsorption force. This can ensure the etching rate and the uniformity of the shape within the sample surface.

What is claimed is:

1. A sample-holding electrode provided in a processing chamber to which a sample is disposed, the electrode comprising:
a dielectric film having a sample-placing surface;
a thin electrode film disposed so as to oppose to the sample-placing surface by way of the dielectric film, including a layer having a substantially same height serving both as a static adsorption electrode and a heater electrode; and
a power source device capable of simultaneously supplying an AC power for heater and DC power for static adsorption to the thin electrode film.

2. A sample-holding electrode according to claim 1,
wherein the thin electrode film comprises a substantially identical metal thin film, and
wherein the layer of the metal thin film is put between upper and lower dielectric films and the upper dielectric film has the sample-placing surface.

3. A sample-holding electrode according to claim 2, wherein the metal thin film comprises a laminate structure formed of a flame sprayed film.

4. A sample-holding electrode according to claim 2, wherein the resistivity of the metal thin film formed between the dielectric films is controlled by W or a metal alloy.

5. A sample-holding electrode according to claim 1,
wherein the thin electrode film comprises an outer adsorption electrode and an inner adsorption electrode each of a substantially identical area, and includes:
common areas disposed to the outer adsorption electrode and the inner adsorption electrode, respectively;
at least one branch area connected by way of a bridge portion to at least one of the common areas;
a DC power source device for applying a DC power between the outer adsorption electrode and the inner adsorption electrode; and
an AC power source device for applying an AC heater power to both ends of each of the common areas.

6. A sample-holding electrode according to claim 5, wherein the common area comprises a band-like electrode area having a predetermined width as a planar shape, which is formed spirally in a circumferential direction by a plurality of turns by way of a radial gap.

7. A sample-holding electrode according to claim 1,
wherein the thin electrode film is constituted as a band-like electrode surface capable of substantially covering approximately the entire surface of the sample-placing surface, and has heater terminals by the number of three or more in total disposed to both ends of the continuous band-like electrode surface and between them,
the sample-holding electrode comprising:
a DC power source device for applying a DC power to the thin electrode film; and
a plurality of AC power source devices capable of controlling the output for applying an AC heater power which is connected between the three or more of heater terminals.

8. A plasma processing apparatus comprising:
a processing chamber the inside of which is evacuated;
a sample-holding electrode provided in the processing chamber with a sample being disposed thereon;
an electromagnetic wave generation device for generating plasmas in the processing chamber;
a gas supply system for supplying a processing gas into the processing chamber; and
an evacuating and exhausting system for exhausting the inside of the processing chamber,
wherein the sample-holding electrode includes:
a dielectric film having a sample-placing surface;
a thin electrode film disposed so as to oppose to the sample-placing surface by way of the dielectric film which has a layer having a substantially same height serving both as a static adsorption electrode and a heater electrode; and
a power source device capable of simultaneously supplying an AC power for heater and a DC power for static adsorption to the thin electrode film.

9. A plasma processing apparatus according to claim 8,
wherein the thin electrode film comprises an outer adsorption electrode and an inner adsorption electrode each of a substantially identical area, and includes:
common areas disposed to the outer adsorption electrode and the inner adsorption electrode respectively;
at least one branch area connected by way of a bridge portion to at least one of the common areas; and
a DC power source device for applying a DC power between the outer adsorption electrode and the inner adsorption electrode; and
an AC power source device for applying a AC heater power to both ends of each of the common areas.

10. A plasma processing apparatus according to claim 8,
wherein the thin electrode film is constituted as a band-like electrode surface capable of substantially covering the approximately entire surface of the sample-placing surface, and includes heater terminals by the number of three or more in total disposed to both ends of a continuous band-like electrode surface and between them,
the plasma processing apparatus comprising:
a DC power source device for supplying a DC power to the thin electrode film; and
a plurality of AC power source devices capable of controlling the output for applying an AC heater power which is connected between three or more of the terminals.
